(19) United States
(12) Patent Application Publication
(10) Pub. No.: US 2026/0300580 A1
(43) Pub. Date: Oct. 1, 2026

(54) ARTIFICIAL-INTELLIGENCE-DRIVEN FUTURE STATE SIMULATION FOR DESIGN COLLABORATION

(71) Applicant: BOOMI, LP, Conshohocken, PA (US)

(72) Inventors: Eric FENNELL, Cambridge, MA (US); Michael J. HUDSON, Delray Beach, FL (US)

(73) Assignee: BOOMI, LP, Conshohocken, PA (US)

(21) Appl. No.: 19/095,987

(22) Filed: Mar. 31, 2025

(51) Int. Cl. G06F 30/27; G06F 9/451

(52) U.S. Cl. CPC G06F 30/27; G06F 9/451

(57) ABSTRACT

Disclosed embodiments are directed to a collaboration model for software development that is driven by artificial intelligence (AI). In particular, an AI agent may provided as another member of a development team. The AI agent may utilize one or more generative AI models to synthesize a workflow model of a software entity to be developed, generate future state simulations of the software entity, and/or generate a project development timeline, including a sequence of well-defined agile sprints.

### BACKGROUND

### Field of the Invention

The embodiments described herein are generally directed to artificial intelligence (AI), and, more particularly, to AI-driven future state simulation for design collaboration.

### Description of the Related Art

In a typical software project, a team of developers will collaborate, to leverage their respective skills and perspectives, for the design and development of a software product. One common collaboration model is 3-in-a-box (3IAB). In a 3IAB collaboration model, the development team consists of three roles: product management, design, and engineering. The product manager may define the product vision, strategy, and roadmap, prioritize features based on customer demand and business objectives, work with stakeholders to align the direction of the product with the stakeholders'perspectives, and/or the like. The designer focuses on the user experience (UX) and user interface (UI) and may conduct user research, prototyping, and usability testing, ensure that the product is intuitive, accessible, and visually appealing, and/or the like. The engineer develops the software code for the product, and may oversee the technical feasibility and architecture of the product, the scalability and performance of the product, the quality of the software code, and/or the like. Collectively, these roles are intended to balance business goals, user experience, and technical constraints during development of the software product.

Software products may be developed iteratively. Commonly, the team members collaborate in agile sprints, to continuously refine the product. In this context, “agile” refers to a flexible, iterative approach that emphasizes cross-functional collaboration, user feedback, incremental delivery, and adaptability, and allows for adaptation to any changes in requirements, to deliver the software product quickly and efficiently. A “sprint” refers to a time-boxed iteration in which the development team works on a prioritized set of tasks to deliver a usable increment of the software product. In a typical sprint, the team may select tasks (e.g., use cases, component(s) to be built, bugs, etc. from the product backlog) to work on during the sprint, collaborate to complete the selected tasks (e.g., via daily or weekly stand-up meetings in which team members discuss progress, roadblocks, next steps, and the like), perform a final review at the end of the sprint that demonstrates the completed work to stakeholders for feedback, and reflect on what did and did not go well during the sprint and improvements for the next sprint. Agile sprints ensure continuous progress with regular releases, keep the development team focused and aligned with business goals, encourage adaptability, and improve collaboration and transparency.

Generally, collaboration, whether using a 3IAB or other collaboration model, relies on static documentation, such as diagrams and text, which can be difficult to interpret and visualize in a holistic manner. Existing artificial intelligence (AI) tools for the development of software products focus on discrete interactions or functional components, such as the generation of test cases or code snippets. There is no AI tool that is capable of providing the “big picture” of how different system components and personas interact, to achieve the overall goal of the software product. As a result, design decisions are often made without a clear, dynamic understanding of the complete system behavior and user journey.

### SUMMARY

Accordingly, systems, methods, and non-transitory computer-readable media are disclosed for AI-driven future state simulation for design collaboration. Embodiments may provide comprehensive AI-generated future state simulations that demonstrates the interplay of system architecture, personas, and use cases for a software product, thereby facilitating early and informed design adjustments during development of the software product. Embodiments may also utilize artificial intelligence to generate a project development timeline, including a sequence of agile sprints.

In an embodiment, a method comprises using at least one hardware processor to, by an artificial intelligence (AI) agent, within a real-time chat session between at least one user and the AI agent: receive a user request from the at least one user for a future state simulation that simulates a future state of a software entity; retrieve design data for the software entity; extract a plurality of attributes from the design data; synthesize a workflow model of the software entity based on the plurality of attributes; apply at least one generative AI model to input data, comprising a representation of the workflow model, to generate the future state simulation; and display the future state simulation within a graphical user interface. The user request may comprise a natural-language expression. In an embodiment, the software entity has not yet been built.

The design data may comprise one or more of a specification of each of one or more use cases, a profile of each of one or more personas, one or more diagrams of an architecture of the software entity, one or more user stories, project management data, a database of requirements for the software entity, one or more software components that are available for incorporation into the software entity, or a user-interface framework to be used by the software entity.

The plurality of attributes may comprise one or more of roles of personas, identification of one or more software components, one or more data flows, one or more user actions, one or more use cases, or cardinalities for relationships between software components.

The at least one generative AI model may comprise a generative video model, wherein the future state simulation comprises a video, generated by the generative video model, depicting a use case represented by the workflow model, and wherein the use case comprises a sequence of one or more interactions between a user persona and the software entity.

The at least one generative AI model may comprise an interactive demonstration of the software entity, wherein the interactive demonstration comprises a simulated version of the software entity with which users can interact, and wherein displaying the future state simulation comprises executing the interactive demonstration within a simulated environment.

The at least one generative AI model may comprise a large language model, wherein the future state simulation comprises a narrative script, generated by the large language model, of a use case represented by the workflow model, and wherein the use case comprises a sequence of one or more interactions between a user persona and the software entity.

The future state simulation may comprise a data-driven simulation of the software entity that incorporates one or both of real or synthetic data to demonstrate an impact of one or more metrics on a user experience of the software entity.

The at least one generative AI model may comprise a generative coding model, wherein the future state simulation comprises one or more software components of the software entity.

The at least one generative AI model may comprise a generative image model, wherein the future state simulation comprises a storyboard that includes one or more drawings, generated by the generative image model, and wherein the one or more drawings depict a use case represented by the workflow model. The at least one generative AI model may further comprise a generative language model, wherein the storyboard includes a narrative description, generated by the generative language model, of each of the one or more drawings.

The workflow model may comprise a graph representation of at least one use case, wherein the graph representation comprises a plurality of nodes and a plurality of edges connecting the plurality of nodes to each other, wherein each of the plurality of nodes represents a user action, event, or response or behavior of the software entity, and wherein each of the plurality of edges represents a relationship between two of the plurality of nodes.

The method may further comprise using the at least one hardware processor to, by the AI agent, within the real-time chat session: receive a user request from the at least one user for a project development timeline; retrieve second design data for the software entity; extract a second plurality of attributes from the second design data; apply at least one second generative AI model to second input data, comprising the second plurality of attributes, to generate the project development timeline; and display the project development timeline within the graphical user interface. The at least one second generative AI model may comprise a large language model, wherein applying the at least one second generative AI model comprises: generating a prompt based on the second input data; and inputting the prompt to the at least one second generative AI model to produce the project development timeline.

Applying the at least one generative AI model may comprise: generating a prompt based on the input data; and inputting the prompt to the at least one generative AI model to produce the future state simulation.

The input data may further comprise at least a subset of the plurality of attributes.

The real-time chat session may be an audiovisual tele-conference, wherein the AI agent is a participant, along with the at least one user, in the audiovisual tele-conference.

It should be understood that any of the features in the methods above may be implemented individually or with any subset of the other features in any combination. Thus, to the extent that the appended claims would suggest particular dependencies between features, disclosed embodiments are not limited to these particular dependencies. Rather, any of the features described herein may be combined with any other feature described herein, or implemented without any one or more other features described herein, in any combination of features whatsoever. In addition, any of the methods, described above and elsewhere herein, may be embodied, individually or in any combination, in executable software modules of a processor-based system, such as a server, and/or in executable instructions stored in a non-transitory computer-readable medium.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 illustrates an example infrastructure, in which one or more of the processes described herein may be implemented, according to an embodiment;

FIG. 2 illustrates an example processing system, by which one or more of the processes described herein may be executed, according to an embodiment;

FIG. 3 illustrates a process for executing an artificial intelligence (AI) agent, according to an embodiment;

FIGS. 4A and 4B illustrate processes for example operations of an AI agent, according to an embodiment; and

FIG. 5 illustrates an example data flow in an example design collaboration with an AI agent, according to an embodiment.

### DETAILED DESCRIPTION

In an embodiment, systems, methods, and non-transitory computer-readable media are disclosed for artificial-intelligence-driven future state simulation for design collaboration. In particular, embodiments may utilize an artificial intelligence (AI) agent to generate comprehensive future state simulations from design data for a software product to be built. The AI agent may analyze use cases, architectural diagrams, persona profiles, and/or the like, and generate dynamic, visual and/or narrative simulations of the software product (e.g., using generative AI models), which may represent cardinality and other usage-related data. This enables stakeholders in the design to visualize the overall user journey and software behavior, beyond just isolated user interactions. Embodiments may facilitate collaborative design by providing a holistic understanding of the proposed software product's functionality and user experience, including the interplay between personas, components of the software product, and data flow through the software product. This enables early identification of potential issues and improved decision-making during the development process. Embodiments may also generate a project development timeline, including a sequence of agile sprints, to facilitate the workflow of the project itself.

After reading this description, it will become apparent to one skilled in the art how to implement the invention in various alternative embodiments and alternative applications. However, although various embodiments of the present invention will be described herein, it is understood that these embodiments are presented by way of example and illustration only, and not limitation. As such, this detailed description of various embodiments should not be construed to limit the scope or breadth of the present invention as set forth in the appended claims.

### 1. Infrastructure

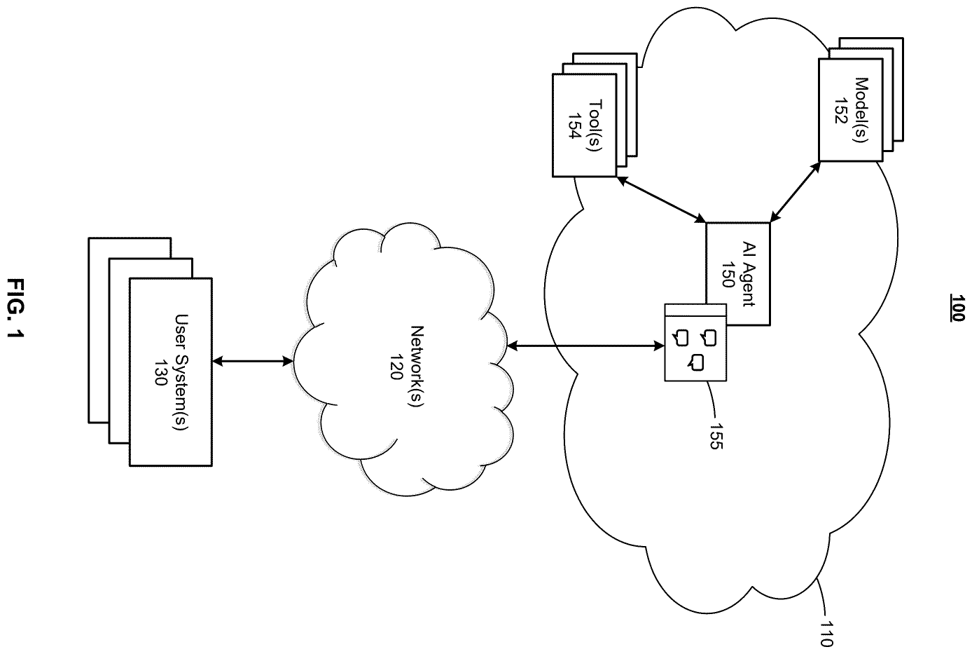

FIG. 1 illustrates an example infrastructure 100, in which one or more of the processes described herein may be implemented, according to an embodiment. Infrastructure 100 may comprise a computing environment 110 which hosts and/or executes one or more of the disclosed processes, which may be implemented in software and/or hardware. Computing environment 110 is generally contemplated to be a server-based platform. The servers may be collocated and/or geographically distributed within one or more data centers. In an embodiment, computing environment 110 is a cloud-computing environment in which computing services are dynamically and elastically allocated to one or more tenants based on demand. The cloud-computing environment may be a public cloud (e.g., owned and operated by a different entity than the tenant(s)), a private cloud (e.g., dedicated to a single entity), or a hybrid cloud (e.g., comprising a combination of public and private cloud elements).

Computing environment 110 may be communicatively connected to one or more networks 120. Network(s) 120 enable communication between computing environment 110 and one or more user systems 130. Network(s) 120 may comprise the Internet, and communication through network(s) 120 may utilize standard transmission protocols, such as HyperText Transfer Protocol (HTTP), HTTP Secure (HTTPS), File Transfer Protocol (FTP), FTP Secure (FTPS), Secure Shell FTP (SFTP), and the like, as well as proprietary protocols. While computing environment 110 is illustrated as being connected to a plurality of user systems 130 through a single set of network(s) 120, it should be understood that computing environment 110 may be connected to different user systems 130 via different sets of one or more networks. For example, computing environment 110 may be connected to a subset of user systems 130 via the Internet, but may be connected to another subset of user systems 130 via an intranet.

While only a few user systems 130 are illustrated, it should be understood that computing environment 110 may be communicatively connected to any number of user system(s) 130 via network(s) 120. User system(s) 130 may comprise any type or types of computing devices capable of wired and/or wireless communication, including without limitation, desktop computers, laptop computers, tablet computers, smart phones or other mobile phones, servers, game consoles, televisions, set-top boxes, electronic kiosks, point-of-sale terminals, and/or the like. However, it is generally contemplated that a user system 130 would be the personal or professional workstation of a member of a software-development team that has a user account for accessing an AI agent 150 in computing environment 110.

Computing environment 110 may host at least one AI agent 150. An AI agent 150 is a software entity that utilizes artificial intelligence (e.g., machine learning, natural-language processing, data analytics, etc.) to autonomously perform a task, in order to achieve an objective set by a human, other AI agent, or other system. An AI agent may collect data, analyze data, learn and improve, communicate with human users and/or other software entities, collaborate with other AI agents to complete a complex task, execute actions, and/or the like. Advantages of AI agents include, without limitation, enhanced efficiency, improved customer satisfaction, perpetual availability, scalability, data-driven insight, consistency, accuracy, and the like.

The user of a user system 130 may interact with an AI agent 150, via user interface 155, to perform a task, for example, during the development of a software product, comprising one or more software entities. It should be understood that multiple users, on multiple user systems 130, may interact with the same AI agent 150 and/or different AI agent 150 in this manner, according to the permissions or roles of their associated user accounts. Although only a single AI agent 150 is illustrated, it should be understood that, in reality, computing environment 110 may comprise any number of AI agents 150 and/or a plurality of instances of the same AI agent 150.

In an embodiment, computing environment 110 is an integration platform as a service (iPaaS) platform. In this case, computing environment 110 may comprise one or a plurality of integration platforms that each comprises one or a plurality of integration processes. Each integration platform may be associated with an organization, which may be associated with one or more user accounts by which respective user(s) manage the organization's integration platform, including the various integration process(es). An integration process may represent a transaction involving the integration of data between two or more systems, and may comprise a series of elements that specify logic and transformation requirements for the data to be integrated. Each element, which may also be referred to as a “step,” may transform, route, and/or otherwise manipulate data to attain an end result from input data. For example, a basic integration process may receive data from one or more data sources, manipulate the received data in a specified manner (e.g., including mapping, analyzing, normalizing, altering, updating, enhancing, and/or augmenting the received data), and send the manipulated data to one or more specified destinations (e.g., via an application programming interface of each destination). An integration process may represent a business workflow or a portion of a business workflow or a transaction-level interface between two systems, and comprise, as one or more elements, software modules that process data to implement the business workflow or interface. A business workflow may comprise any myriad of workflows of which an organization may repetitively have need. For example, a business workflow may comprise, without limitation, procurement of parts or materials, manufacturing a product, selling a product, shipping a product, ordering a product, billing, managing inventory or assets, providing customer service, ensuring information security, marketing, onboarding or offboarding an employee, assessing risk, obtaining regulatory approval, reconciling data, auditing data, providing information technology services, and/or any other workflow that an organization may implement in software.

The operator of the iPaaS platform may provide one or more AI agents, including AI agent 150, to aid users in the management of their integration platforms, including the development of integration processes for their integration platforms. For instance, AI agents may be utilized within an iPaaS platform to autonomously perform integration-related tasks, such as customer support, software design, code generation, conversational assistance, and the like. For example, an AI agent could be used to automatically map and/or transform data, orchestrate and/or optimize workflows, identify patterns and predict potential issues with integration processes, detect and/or resolve errors in integration processes, design steps in an integration process and/or entire integration processes based on a natural-language input from a user, otherwise interact with users through natural language, dynamically scale and adjust integration processes and/or the runtimes in which they execute, detect and/or mitigate security threats or compliance risks, identify and protect personally identifiable information, discover application programming interfaces (APIs), optimize API calls, monitor parameters of integration processes and/or integration platforms in real time for real-time alerts, provide next-step best practices, document integration processes (e.g., for improved version control), provide technical support, streamline data synchronization, enhance data quality, and/or the like. Of particular relevance to disclosed embodiments, an AI agent 150 is configured to collaborate with a software development team to generate future state simulations, project development timelines, and/or the like.

In an embodiment, AI agent 150 comprises or is communicatively coupled to at least one AI model 152. An AI model 152 may be a generative AI model, such as a generative language model (e.g., small language model, large language model, etc., that responds to natural-language prompts in natural language), generative image model (e.g., that responds to a natural-language prompt with an image), generative video model (e.g., that responds to a natural-language prompt with a video), generative coding model (e.g., that responds to a natural-language prompt with software code), or the like. One well-known example of a large language model is the Generative Pre-trained Transformer (GPT). GPT-4 is the fourth-generation language prediction model in the GPT-n series, created by OpenAI of San Francisco, California. GPT-4 is an autoregressive language model that uses deep learning to produce human-like text. GPT-4 has been pre-trained on a vast amount of text from the open Internet. While GPT-4 is provided as an example, it should be understood that the generative language model may be any generative language model, including past and future generations of GPT, as well as other large language models, such as any of the DeepSeek family of large language models from DeepSeek AI of Hangzhou, Zhejiang, China, any of the Claude family of large language models (e.g., Claude 3 Opus) developed by Anthropic PBC of San Francisco, California, the Falcon large language model (e.g., Falcon 160B) released by the United Arab Emirates'Technology Innovation Institute (TII), the Large Language Model Meta AI (LLaMA) model (e.g., LLaMA 2) released by Meta AI of New York, New York, the Gemini model, the Mistral family of models released by Mistral AI of Paris, France, and the like. Examples of generative image models include, without limitation, the DALL-E family of models (e.g., DALL-E, DALL-E 2, or DALL-E 3) from OpenAI, Stable Diffusion (e.g., SD 3.5) from Stability AI Ltd of London, England, United Kingdom, Imagen (e.g., Imagen 3) from Google LLC of Mountain View, California, Midjourney form Midjourney, Inc. of San Francisco, California, Adobe Firefly from Adobe Inc. of San Jose, California, Picasso from Nvidia Corp. of Santa Clara, California, Runway Gen-2 from Runway AI, Inc. of New York City, New York, and the like. Examples of generative video models include, without limitation, Runway Gen-2, the Pika family of models from Pika Labs AI of San Francisco, California, Lumiere from Google LLC, VideoLDM from Nvidia, Make-A-Video from Meta Platforms, Inc. of Menlo Park, California, Synthesia from Synthesia of London, England, United Kingdom, DeepBrain AI from AI Studios of Palo Alto, California, Stable Video Diffusion from Stability AI Ltd, and the like. Examples of generative coding models include, without limitation, Codex from OpenAI, AlphaCode from Google LLC, Code LLaMA from Meta AI, AlphaFold Code from DeepMind Technologies Limited of London, England, United Kingdom, CodeWhisperer from Amazon Web Services of Seattle, Washington, CodeGen from Salesforce, Inc. of San Francisco, California, StarCoder developed by Hugging Face and ServiceNow Research, Tabnine from Tabnine of Tel Aviv, Israel, and the like. A pre-trained generative AI model may used as a base model that is fine-tuned for the specific task of AI agent 150 (e.g., generating future state simulations and/or project development timelines).

In an embodiment, AI agent 150 may comprise or be communicatively coupled to zero, one, or a plurality of tools 154. Tool(s) 154 may be hosted within computing environment 110 (e.g., a cloud-computing environment) and/or externally to computing environment 110. Each tool 154 may perform a sub-task for the overall task of AI agent 150. A sub-task may comprise retrieving data from a source (e.g., another AI agent, a local database hosted within computing environment 110, a remote database hosted externally to computing environment 110, a third-party system, application, or database, an integration process, etc.), transforming, formatting, mapping, cleaning, or otherwise manipulating data, analyzing data, storing data, sending data (e.g., tabular or other structured data, unstructured data, commands, requests, queries, etc.) to a destination (e.g., another AI agent, a local database, a remote database, a third-party system, application, or database, an integration process, etc.), initiating a transaction (e.g., purchase, sale, exchange, trade, etc.), completing a transaction, and/or the like.

In a contemplated embodiment, AI agent 150 implements a real-time chat session, in which at least one user chats or otherwise interacts with AI agent 150 in real time, via user interface 155, which may comprise or consist of a graphical user interface, audio interface, audiovisual interface, and/or the like. During this chat session, AI agent 150 may utilize one or more models 152 and/or tools 154, to facilitate the development of a software product. In a preferred embodiment, AI agent 150 may act as a member of the development team, for example, to listen to the discussion, retrieve and present relevant data, generate future state simulations of the product, generate project development timelines, and/or the like. In this sense, AI agent 150 may facilitate a 4-in-a-box (4IAB) collaboration model, in which AI agent 150 fills an AI role, to support the product management, design, and engineering roles.

### 2. Example Processing System

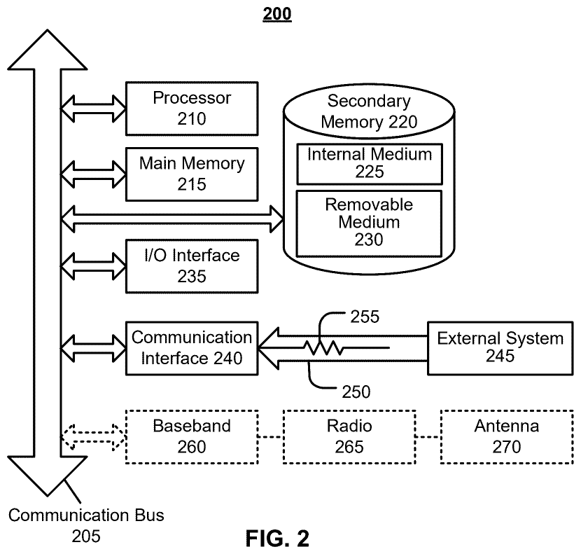

FIG. 2 illustrates an example processing system, by which one or more of the processes described herein may be executed, according to an embodiment. For example, system 200 may be used to store and/or execute AI agent 150, and/or may represent components of computing environment 110, user system(s) 130, and/or other processing devices described herein. System 200 can be any processor-enabled device (e.g., server, personal computer, etc.) that is capable of wired or wireless data communication. Other processing systems and/or architectures may also be used, as will be clear to those skilled in the art.

System 200 may comprise one or more processors 210. Processor(s) 210 may comprise a central processing unit (CPU). Additional processors may be provided, such as a graphics processing unit (GPU), an auxiliary processor to manage input/output, an auxiliary processor to perform floating-point mathematical operations, a special-purpose microprocessor having an architecture suitable for fast execution of signal-processing algorithms (e.g., digital-signal processor), a subordinate processor (e.g., back-end processor), an additional microprocessor or controller for dual or multiple processor systems, and/or a coprocessor. Such auxiliary processors may be discrete processors or may be integrated with a main processor 210. Examples of processors which may be used with system 200 include, without limitation, any of the processors (e.g., Pentium™, Core i7™, Core i9™, Xeon™, etc.) available from Intel Corporation of Santa Clara, California, any of the processors available from Advanced Micro Devices, Incorporated (AMD) of Santa Clara, California, any of the processors (e.g., A series, M series, etc.) available from Apple Inc. of Cupertino, any of the processors (e.g., Exynos™) available from Samsung Electronics Co., Ltd., of Seoul, South Korea, any of the processors available from NXP Semiconductors N.V. of Eindhoven, Netherlands, any of the processors available from Nvidia Corporation of Santa Clara, California, and/or the like.

Processor(s) 210 may be connected to a communication bus 205. Communication bus 205 may include a data channel for facilitating information transfer between storage and other peripheral components of system 200. Furthermore, communication bus 205 may provide a set of signals used for communication with processor 210, including a data bus, address bus, and/or control bus (not shown). Communication bus 205 may comprise any standard or non-standard bus architecture such as, for example, bus architectures compliant with industry standard architecture (ISA), extended industry standard architecture (EISA), Micro Channel Architecture (MCA), peripheral component interconnect (PCI) local bus, standards promulgated by the Institute of Electrical and Electronics Engineers (IEEE) including IEEE 488 general-purpose interface bus (GPIB), IEEE 696/S-100, and/or the like.

System 200 may comprise main memory 215. Main memory 215 provides storage of instructions and data for programs executing on processor 210, such as any of the software discussed herein. It should be understood that programs stored in the memory and executed by processor 210 may be written and/or compiled according to any suitable language, including without limitation C/C++, Java, JavaScript, Perl, Python, Visual Basic, .NET, and the like. Main memory 215 is typically semiconductor-based memory such as dynamic random access memory (DRAM) and/or static random access memory (SRAM). Other semiconductor-based memory types include, for example, synchronous dynamic random access memory (SDRAM), Rambus dynamic random access memory (RDRAM), ferroelectric random access memory (FRAM), and the like, including read only memory (ROM).

System 200 may comprise secondary memory 220. Secondary memory 220 is a non-transitory computer-readable medium having computer-executable code and/or other data (e.g., any of the software disclosed herein) stored thereon. In this description, the term “computer-readable medium” is used to refer to any non-transitory computer-readable storage media used to provide computer-executable code and/or other data to or within system 200. The computer software stored on secondary memory 220 is read into main memory 215 for execution by processor 210. Secondary memory 220 may include, for example, semiconductor-based memory, such as programmable read-only memory (PROM), erasable programmable read-only memory (EPROM), electrically erasable read-only memory (EEPROM), and flash memory (block-oriented memory similar to EEPROM).

Secondary memory 220 may include an internal medium 225 and/or a removable medium 230. Internal medium 225 and removable medium 230 are read from and/or written to in any well-known manner. Internal medium 225 may comprise one or more hard disk drives, solid state drives, and/or the like. Removable storage medium 230 may be, for example, a magnetic tape drive, a compact disc (CD) drive, a digital versatile disc (DVD) drive, other optical drive, a flash memory drive, and/or the like.

System 200 may comprise an input/output (I/O) interface 235. I/O interface 235 provides an interface between one or more components of system 200 and one or more input and/or output devices. Examples of input devices include, without limitation, sensors, keyboards, touch screens or other touch-sensitive devices, cameras, biometric sensing devices, computer mice, trackballs, pen-based pointing devices, and/or the like. Examples of output devices include, without limitation, other processing systems, cathode ray tubes (CRTs), plasma displays, light-emitting diode (LED) displays, liquid crystal displays (LCDs), printers, vacuum fluorescent displays (VFDs), surface-conduction electron-emitter displays (SEDs), field emission displays (FEDs), and/or the like. In some cases, an input and output device may be combined, such as in the case of a touch-panel display (e.g., in a smartphone, tablet computer, or other mobile device).

System 200 may comprise a communication interface 240. Communication interface 240 allows software to be transferred between system 200 and external devices, networks, or other information sources. For example, computer-executable code and/or data may be transferred to system 200 from a network server via communication interface 240. Examples of communication interface 240 include a built-in network adapter, network interface card (NIC), Personal Computer Memory Card International Association (PCMCIA) network card, card bus network adapter, wireless network adapter, Universal Serial Bus (USB) network adapter, modem, a wireless data card, a communications port, an infrared interface, an IEEE 1394 fire-wire, and any other device capable of interfacing system 200 with a network (e.g., network(s) 120) or another computing device. Communication interface 240 preferably implements industry-promulgated protocol standards, such as Ethernet IEEE 802 standards, Fiber Channel, digital subscriber line (DSL), asynchronous digital subscriber line (ADSL), frame relay, asynchronous transfer mode (ATM), integrated digital services network (ISDN), personal communications services (PCS), transmission control protocol/Internet protocol (TCP/IP), serial line Internet protocol/point to point protocol (SLIP/PPP), and so on, but may also implement customized or non-standard interface protocols as well.

Software transferred via communication interface 240 is generally in the form of electrical communication signals 255. These signals 255 may be provided to communication interface 240 via a communication channel 250 between communication interface 240 and an external system 245. In an embodiment, communication channel 250 may be a wired or wireless network (e.g., network(s) 120), or any variety of other communication links. Communication channel 250 carries signals 255 and can be implemented using a variety of wired or wireless communication means including wire or cable, fiber optics, conventional phone line, cellular phone link, wireless data communication link, radio frequency (“RF”) link, or infrared link, just to name a few.

Computer-executable code is stored in main memory 215 and/or secondary memory 220. Computer-executable code can also be received from an external system 245 via communication interface 240 and stored in main memory 215 and/or secondary memory 220. Such computer-executable code, when executed, enables system 200 to perform one or more of the various processes disclosed herein.

In an embodiment that is implemented using software, the software may be stored on a computer-readable medium and initially loaded into system 200 by way of removable medium 230, I/O interface 235, or communication interface 240. In such an embodiment, the software is loaded into system 200 in the form of electrical communication signals 255. The software, when executed by processor 210, may cause processor 210 to perform one or more of the various processes disclosed herein.

System 200 may optionally comprise wireless communication components that facilitate wireless communication over a voice network and/or a data network (e.g., in the case of user system 130). The wireless communication components comprise an antenna system 270, a radio system 265, and a baseband system 260. In system 200, radio frequency (RF) signals are transmitted and received over the air by antenna system 270 under the management of radio system 265.

In an embodiment, antenna system 270 may comprise one or more antennae and one or more multiplexors (not shown) that perform a switching function to provide antenna system 270 with transmit and receive signal paths. In the receive path, received RF signals can be coupled from a multiplexor to a low noise amplifier (not shown) that amplifies the received RF signal and sends the amplified signal to radio system 265.

In an alternative embodiment, radio system 265 may comprise one or more radios that are configured to communicate over various frequencies. In an embodiment, radio system 265 may combine a demodulator (not shown) and modulator (not shown) in one integrated circuit (IC). The demodulator and modulator can also be separate components. In the incoming path, the demodulator strips away the RF carrier signal leaving a baseband receive audio signal, which is sent from radio system 265 to baseband system 260.

If the received signal contains audio information, baseband system 260 decodes the signal and converts it to an analog signal. Then, the signal is amplified and sent to a speaker. Baseband system 260 also receives analog audio signals from a microphone. These analog audio signals are converted to digital signals and encoded by baseband system 260. Baseband system 260 also encodes the digital signals for transmission and generates a baseband transmit audio signal that is routed to the modulator portion of radio system 265. The modulator mixes the baseband transmit audio signal with an RF carrier signal, generating an RF transmit signal that is routed to antenna system 270 and may pass through a power amplifier (not shown). The power amplifier amplifies the RF transmit signal and routes it to antenna system 270, where the signal is switched to the antenna port for transmission.

Baseband system 260 may be communicatively coupled with processor(s) 210, which have access to memory 215 and 220. Thus, software can be received from baseband processor 260 and stored in main memory 210 or in secondary memory 220, or executed upon receipt. Such software, when executed, can enable system 200 to perform one or more of the various processes disclosed herein.

### 3. Example Execution of AI Agent

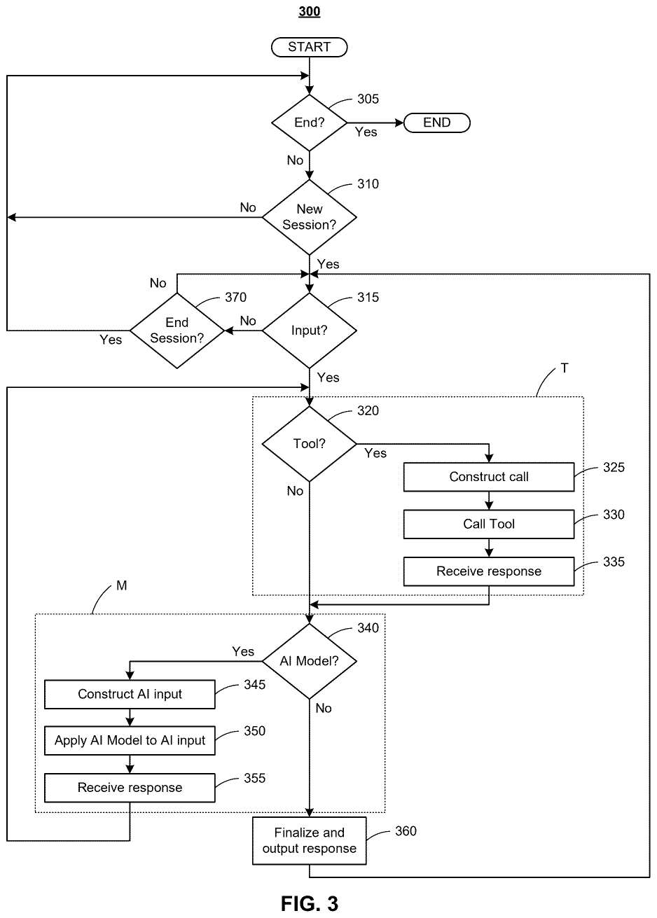

FIG. 3 illustrates a process 300 for executing an artificial intelligence (AI) agent 150, according to an embodiment. Process 300 may be implemented by each AI agent 150, once that AI agent 150 has been deployed (e.g., within computing environment 110), and during execution of that AI agent 150, and may be triggered by a user operation (e.g., via user interface 155, or another or overarching user interface, such as the graphical user interface of a virtual meeting tool, i.e., a software application that provides audiovisual tele-conferencing). For the sake of explication, it is assumed, for the purposes of describing process 300, that AI agent 150 is a chat agent that implements real-time chat sessions with users. The real-time chat sessions may be visual (e.g., textual, graphical, etc.), audial, or audiovisual. However, it should be understood that process 300 may be modified to suit other types of interactions with AI agent 150.

While process 300 is illustrated with a certain arrangement and ordering of subprocesses, process 300 may be implemented with fewer, more, or different subprocesses and a different arrangement and/or ordering of subprocesses. Furthermore, any subprocess, which does not depend on the completion of another subprocess, may be executed before, after, or in parallel with that other independent subprocess, even if the subprocesses are described or illustrated in a particular order.

Subprocess 305 may determine whether or not to end process 300. Process 300 may be performed for as long as the implementing AI agent 150 is operational. Once AI agent 150 has been deployed, process 300 may be performed until AI agent 150 is undeployed or otherwise terminated. For as long as the operation of AI agent 150 continues (i.e., “No” in subprocess 305), process 300 may proceed to subprocess 310. Otherwise, when the operation of AI agent 150 ends (i.e., “Yes” in subprocess 305), process 300 may end.

Subprocess 310 may determine whether or not to initiate a new session between a user and AI agent 150. The initiation of a new session may be triggered by a user operation, such as the selection of an input by the user within the graphical user interface of user interface 155, the navigation of the user to a particular screen of the graphical user interface, and/or the like. When determining to initiate a new session (i.e., “Yes” in subprocess 310), process 300 may proceed to subprocess 315 to begin the new session. Otherwise, while not determining to initiate a new session (i.e., “No” in subprocess 310), process 300 may return to subprocess 305, for example, to await the initiation of a new session or the end of process 300.

While process 300 is generally described with respect to a single user, it should be understood that, in practice, a session may between AI agent 150 and a plurality of users. In particular, the plurality of users may comprise or consist of a development team. As an example, this development team may comprise at least a product manager, designer, and software engineer. AI agent 150 may act as an additional member of the development team, and may interact with any one or more of the plurality of users, just as any other member of the development team.

In a contemplated embodiment, each session is a real-time chat session, in which the user interacts with AI agent 150 using natural-language inputs, and AI agent 150 interacts with the user using natural-language responses. The natural-language inputs and/or responses may be provided in a textual format and/or audio format (e.g., using a text-to-speech engine to convert the user's speech to text to be processed by AI agent 150, and/or a speech-to-text engine to convert the textual response of AI agent 150 into speech to be output to the user). As used herein, the term “natural language” or “natural-language” refers to language, including grammar, that would be expected in a normal conversation between two humans. In some cases, the responses from AI agent 150 may comprise non-textual visual elements, such as images, videos, animations, slides, diagrams, storyboards, charts, graphical user interfaces, and/or other graphical content, potentially in combination with textual visual elements and/or audio elements.

Subprocess 315 may determine whether or not a new input has been received within the session. For example, the user may type a textual input into a textbox within the graphical user interface of user interface 155 and then select an input to submit the textual input, speak an audio input into an audio interface of user interface 155 (e.g., which may then be converted to text via a speech-to-text engine), or the like. More generally, the input may be received from a user (e.g., in the context of a real-time chat session), and may comprise or consist of a natural-language expression. Alternatively, the input may be received from another AI agent, an integration process, a third-party application, or the like. When determining that a new input has been received (i.e., “Yes” in subprocess 315), process 300 may proceed to subprocess 320. Otherwise, while not determining that a new input has been received (i.e., “No” in subprocess 315), process 300 may proceed to subprocess 370.

Subprocess 320 may determine whether or not a tool 154 is to be utilized, at the current time, to respond to the input that was received in subprocess 315, based on the current context of the session. For example, a tool 154 may be utilized when AI agent 150 needs to retrieve or send information relevant to the input, perform an action requested by or otherwise in response to the input, and/or perform any other operation that is external to AI agent 150. Tool 154 may provide an application programming interface that provides access to one or more operations available to AI agent 150. When determining that a tool 154 is to be utilized, at the current time, to respond to the input (i.e., “Yes” in subprocess 320), process 300 may select the tool 154 and proceed to subprocess 325. Otherwise, when determining that a tool 154 is not to be utilized, at the current time, to respond to the input (i.e., “No” in subprocess 320), process 300 may proceed to subprocess 340.

Subprocess 325 may construct a call to the selected tool 154 based on the input received in subprocess 315. For example, subprocess 325 may select an operation, from available operations of the tool 154, to be performed by the tool 154, determine the value of one or more input fields to the operation, and/or the like. Thus, subprocess 325 may determine at least one of the operations, available within the application programming interface of tool 154 and available to AI agent 150, to be used in response to the input received in subprocess 315. Subprocess 325 may apply one or more natural-language processing (NLP) techniques to the input to determine which operation to select and the value(s) of any input field(s) for the operation.

Subprocess 330 may submit the call, constructed in subprocess 325, to the selected tool 154. In particular, subprocess 330 may call the selected operation(s) of the selected tool 154, via the application programming interface of the selected tool 154, using the determined value(s) of any input field(s). It should be understood that each call to a selected operation may be a remote procedure call to a function within the application programming interface of the tool 154. In the case of a tool 154 that is external to computing environment 110, this call may be performed across network(s) 120. As examples, the called operation may retrieve and return data, perform an action and return a result of the action, and/or the like.

Subprocess 335 may receive the response to the call that was submitted in subprocess 330. This response may comprise data (e.g., structured data) in the output schema of the selected tool 154, an acknowledgement (e.g., that the call was received, an action was completed, etc.), and/or the like. In general, the response will not be or comprise a natural-language response, unless the tool 154 provides natural-language responses. After receiving the response in subprocess 335, process 300 may proceed to subprocess 340.

Subprocess 340 may determine whether or not an AI model 152 is to be utilized, at the current time, to respond to the input that was received in subprocess 315. For example, a generative AI model may be utilized to generate a response to the input. AI agent 150 may comprise or have access to a single AI model 152 or a plurality of AI models 152. When determining that an AI model 152 is to be utilized, at the current time, to respond to the input (i.e., “Yes” in subprocess 340), process 300 may select the AI model 152 and proceed to subprocess 345. Otherwise, when determining that an AI model 152 is not to be utilized, at the current time, to respond to the input (i.e., “No” in subprocess 340), process 300 may proceed to subprocess 360.

Subprocess 345 may construct an AI input to the selected AI model 152 based on the received user input, and/or the response from each tool 154 in the event that any tools 154 were previously utilized. For example, in an embodiment in which the AI model 152 is a generative AI model, such as a generative language model, generative image model, generative video model, or generative coding model, subprocess 345 may generate a prompt by inserting relevant data, including at least a portion of the user input and/or data from the response of one or more tools 160, into a predefined template. The predefined template may comprise a pre-conversation and/or post-conversation, which provide context and/or instructions for the generative AI model, and one or more placeholders into which the relevant data are inserted. The pre-conversation and/or post-conversation may define the role of the generative AI model (e.g., to summarize the relevant data, generate image or video data or software code from the relevant data, etc.), define an output format for the generative language model (e.g., a list structure, a hierarchical structure, a markup-language structure, etc.), and/or the like. The prompt may comprise or consist of a natural-language expression.

Subprocess 350 may apply the AI model 152 to the AI input that was constructed in subprocess 345. For example, in an embodiment in which the AI model 152 is a generative AI model, the AI input may comprise a prompt (e.g., comprising or consisting of a natural-language expression) that is submitted to the generative AI model. The AI model 152 will process the AI input to produce a response. While it is generally contemplated that the AI model 152 comprises a generative AI model, it should be understood that the AI model 152 could be any type of AI model with any suitable architecture, including without limitation, other types of artificial neural networks, a random forest algorithm, a linear regression algorithm, a logistic regression algorithm, a decision tree, a support vector machine (SVM), a naïve Bayes algorithm, a k-Nearest Neighbors (kNN) algorithm, a K-means algorithm, a dimensionality reduction algorithm, a gradient-boosting algorithm, a Markov chain, a compact prediction tree (CPT), ensemble models, and/or the like.

In an embodiment, one or more AI models 152 may be separate and independent from AI agent 150. In this case, each AI model 152 may provide an application programming interface that defines how AI agent 150 may interact with the AI model 152. For example, the AI model 152 may be provided as a microservice (e.g., within computing environment 110). An AI agent 150 may query the AI model 152, using the AI input, via the application programming interface of the AI model 152. It should be understood that a plurality of AI agents 150 or instances of the same AI agent 150 may utilize the same AI model 152 in this manner.

Subprocess 355 may receive the response to the AI input (i.e., AI output) from the AI model 152. It should be understood that this AI output may comprise or consist of a natural-language expression in the event that the AI model 152 is a generative language model, an image in the event that the AI model 152 is a generative image model, a video in the event that the AI model 152 is a generative video model, software code in the invention that the AI model 152 is a generative coding model, and the like. After receiving the AI output in subprocess 355, process 300 may return to subprocess 320.

Notably, subprocesses 320-335 form a tool subprocess T that acquires a response from a tool 154, and subprocesses 340-355 form a model subprocess M that acquires a response from an AI model 152. It should be understood that these tool and model subprocesses may be performed in any order, depending on the task of AI agent 150 and/or the input received in subprocess 315. For example, if the AI model 152 requires particular data to generate a response, the tool subprocess T may be performed first to retrieve the particular data using a tool 154, and then the model subprocess M may be performed second to process (e.g., summarize, format, generate an image, video, or software code from, etc.) the retrieved data using the AI model 152. In an embodiment in which the AI model 152 is a generative AI model, this may comprise generating a prompt based on the result of a call to at least one operation of at least one tool 154, and inputting the prompt to the generative AI model to produce a response to the input received in subprocess 315. As another example, if a tool 154 requires the output of the AI model 152, the model subprocess M may be performed first to obtain the AI output, and then the tool subprocess T may be performed to submit the AI output to the tool 154 and receive a response from the tool 54. In other words, a response to the input, received in subprocess 315, may be generated using an AI model 152 and a result of a call to at least one operation of a tool 154.

In addition, these tool and model subprocesses may be combined into a larger sequence in which the same tool 154 is used at a plurality of different times (e.g., in which case, the tool subprocess T may be performed at each time, potentially with one or more intervening tool or model subprocesses), a plurality of different tools 154 are used (e.g., in which case, the tool subprocess T may be performed for each tool 54, serially or in parallel), the same AI model 152 is used at a plurality of different times (e.g., in which case, the model subprocess M may be performed at each time, potentially with one or more intervening tool or model subprocesses), a plurality of different AI models 152 are used (e.g., in which case, the model subprocess M may be performed for each model), and/or the like, to generate the response to a single user input. For example, data may be retrieved from a plurality of different tools 154 using parallel tool subprocesses T, and then summarized into a natural-language response using a model subprocess M. As another example, data may be retrieved from one or more tools 154 using tool subprocess(es) T, an action may be determined using a model subprocess M, and the action may be executed by a tool 154 using a tool subprocess T. It should be understood that these are simply a couple examples, and that the AI model(s) 152 and tool(s) 154 may be used in any sequences and combinations that are suitable for the task of AI agent 150.

In some cases, AI agent 150 may need to collect information from a user before AI agent 150 can utilize a tool 154. For example, tool 154 may require a plurality of input fields. In this case, AI agent 150 may execute a series of model subprocesses M to collect the information (e.g., piece by piece), as would be expected in a natural human-to-human interaction, until all of the information, required to determine the values of the input fields, has been obtained from the user. At this point, AI agent 150 could execute a tool subprocess T to call tool 154 using the determined values of the input fields.

Subprocess 360 may finalize and output a response to the input that was received in subprocess 315. Assuming that the input was received from a user, the response may be output to the user, for example, within a chat frame, representing a real-time chat session, in a graphical user interface of user interface 155, through a speaker in an audio user interface of user interface 155, and/or the like. Finalization of the response may comprise formatting the response into a visual representation that can be displayed within the graphical user interface of user interface 155, converting the response from text to speech using a text-to-speech engine for playback at a user system 130, and/or the like. The response may comprise or otherwise be based on one or more responses that were received from an AI model 152 in an iteration of subprocess 355, and/or one or more responses that were received from a tool 154 in an iteration of subprocess 335.

In an embodiment in which AI agent 150 implements a real-time chat session, the final output response may comprise or consist of a natural-language expression. For example, if the user input is a question, the response, returned by AI agent 150, may be an answer to the question. As another example, if the user input is a request to perform an action, the response, returned by AI agent 150, may be a result of the request, such as details of the completed action if AI agent 150 was able to complete the action, or a reason why the action could not be completed if AI agent 150 was unable to complete the action.

Subprocess 370 may determine whether or not to end the current session. AI agent 150 may continue to respond to inputs (e.g., from a user), for as long as the session remains active. The end of a session may be triggered by a user operation, such as the selection of an input, by the user, within the graphical user interface of user interface 155, a vocal input spoken by the user and received via a microphone of user system 130, the navigation of the user away from the screen (e.g., chat frame) in which the interaction with AI agent 150 takes place, the expiration of a timeout period after the most recent user input, and/or the like. When determining to end the session (i.e., “Yes” in subprocess 370), process 300 may return to subprocess 305 and await the end of process 300 or the initiation of a new session (e.g., by the same user or a different user). Otherwise, while not determining to end the session (i.e., “No” in subprocess 370), process 300 may return to subprocess 315 to await a new input.

It should be understood that a single AI agent 150 may service a plurality of users or development teams in their respective collaborations. Thus, iterations of subprocesses 310-370 may be performed in parallel and/or in series for a plurality of different collaborations, with each user or development team interacting with the same AI agent 150 within a different, independent session. In an embodiment, the same AI agent 150 may utilize different tools 154 for different users. For example, two different users may have different on-premise systems, hosting their own respective organization-specific copy of the same tool 154. In this case, AI agent 150 may operate in an identical manner for each of the two users, but when needing to access the tool 154 during one of the user's session, will access the respective organization-specific copy of the tool 154. Consequently, the operations of AI agent 150 may be identical for all users of all organizations, but still capable of providing organization-specific and/or project-specific responses, due to the organization-specific and/or project-specific data being provided by each organization's specific copy of tool(s) 154.

AI agent 150 may execute as a stand-alone software entity, for example, as a software application or a user tool on an iPaaS platform or other platform. Alternatively, AI agent 150 may be integrated into an existing design application, such as Jira from Atlassian of Sydney, Australia, Figma from Figma, Inc. of San Francisco, California, Sketch from Sketch B.V. of Eindhoven, Netherlands, or the like, an existing virtual meeting application, which supports an audiovisual tele-conference, such as Google Meet from Google LLC, Zoom from Zoom Communications, Inc. of San Jose, California, Microsoft Teams from Microsoft Corp. of Redmond, Washington, or the like, a messaging application, such as Slack from Slack Technologies, LLC of San Francisco, California, and/or the like. In this case, user interface 155 may be embedded within the graphical user interface of the existing software application.

In an embodiment, AI agent 150 implements a retrieval-augmented generation (RAG) architecture. The RAG architecture combines a retrieval-based component with a generation-based component. The RAG architecture is particularly effective when a response is to be informed by a large knowledge base. In this case, tool process T represents the retrieval-based component, and model process M represents the generation-based component. In particular, AI agent 150 may execute tool process T to retrieve data from a knowledge base, accessible via tool(s) 154, and then execute model process M to generate a response from the retrieved data using one or more AI models 152. The RAG architecture provides dynamic and scalable access to the knowledge base, improved generalization (e.g., enabling AI model(s) 152 to respond to prompts beyond those for which AI model(s) 152 were trained), and reduced model size (e.g., since AI model(s) 152 do not need to store all relevant data internally). Suitable enhancements to the RAG architecture, which may be used, include Chunked RAG (CRAG), in which the retrieval-based component retrieves relevant chunks of the knowledge corpus, and Self-RAG, in which the retrieval-based component is able to retrieve relevant data from a store of prior responses, as well the knowledge base. In an alternative embodiment, AI agent 150 could comprise only the retrieval-based component (e.g., only tool process T) or only the generation-based component (e.g., only model process M).

### 4. Example Operation of AI Agent

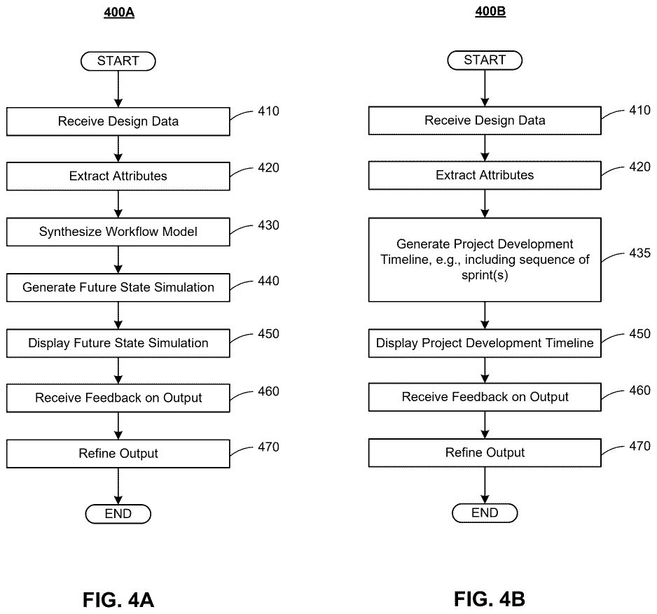

FIG. 4A illustrates a process 400A for generating a future state simulation, according to an embodiment. Process 400A may be implemented by AI agent 150. In particular, AI agent 150 is configured to analyze design artifacts and synthesize these design artifacts into a future state simulation. It should be understood that AI agent 150 may utilize one or more models 152 and/or one or more tools 154 to perform this analysis and synthetization, for example, in one or more iterations of model process M and/or tool process T. For instance, tool(s) 154 may be used to retrieve and/or analyze data, and model(s) 152 may be used to analyze that data and/or generate future state simulations from that data.

Process 400A may be performed by AI agent 150 within a real-time chat session between at least one user and AI agent 150. The real-time chat session may occur within a chat frame of a graphical user interface of user interface 155, through an audio interface, through an audiovisual interface, and/or the like. Process 400A may be initiated in response to receiving a user request from at least one user for a future state simulation. The user request may comprise or consist of a natural-language expression. A future state simulation is any audio and/or visual content that simulates a future state of a software entity. It should be understood that the software entity may be all or a portion (e.g., an increment) of a software product that is to be built. Thus, it should be understood that the software entity will generally not yet have been built to the state for which a simulation has been requested, such that a simulation is the only way to visually represent the requested state of the software entity.

Initially, subprocess 410 may receive design data for the software entity. In particular, AI agent 150 may retrieve or otherwise ingest the design data for the software entity. The design data may comprise a specification of each of one or more use cases (e.g., with sequence diagrams), a profile of each of one or more personas (e.g., list of known personas that will utilize the software entity once built), one or more diagrams of an architecture of the software entity (e.g., representing a service architecture of the software entity), one or more user stories (e.g., short, informal, natural-language descriptions of a feature from the perspective of an end user), project management data (e.g., imported from project-management and/or issue-tracking software, such as Jira™), a database of requirements for the software entity (e.g., comprising standard requirements and/or project-specific requirements for the software product), one or more software components that are available for incorporation into the software product, a user-interface framework to be used by the software entity, and/or the like. The design data may comprise both data and metadata for one or more of these data elements. As used herein, the term “persona” refers to a fictional, yet realistic, representation of a typical or target user of the software entity, including end users, administrative users, decision-makers, and the like. Exemplary personas include, without limitation, user personas, buyer personas, role-based personas, proto personas, customer personas, marketing personas, negative personas, and the like.

Subprocess 420 may extract one or more, and generally a plurality of, attributes from the design data that were received in subprocess 410. In particular, AI agent 150 may utilize natural language processing (NLP) and/or one or more parsing techniques to extract one or more attributes from the design data. These attribute(s) may include, without limitation, one or more roles of personas, identification of one or more software components that are available to or to be used by the software entity, one or more data flows, one or more user actions, one or more use cases, cardinalities for relationships between software components (e.g., one-to-one, one-to-many, many-to-many, many-to-one, etc.), and/or the like. However, it should be understood that the attributes may comprise any attribute or set of attributes that may be relevant to the generation of a workflow model of the software entity and/or a future state simulation of the software entity. An attribute may be extracted directly from the design data or derived indirectly from one or a plurality of data items extracted from the design data.

Subprocess 430 may synthesize a workflow model based on the attribute(s) that were extracted in subprocess 420. As mentioned above, these attribute(s), which will generally be a plurality of attributes, may comprise one or more use cases. As used herein, the term “use case” refers to a specific interaction or sequence of interactions, between the software entity to be built and a user persona or other software entity, that achieves a particular goal. Each use case, within the attribute(s), may be represented by one or more sequence diagrams. In an embodiment, the workflow model, which is synthesized from the attribute(s), represents, for each use case represented in the attributes, the sequence of actions and events required to achieve the goal of the use case, reflecting the interactions between user personas and software components and the flow of data and control for the use case. The workflow model may comprise one or more graph representations and/or other suitable data structures that store representations of these components (e.g., as nodes in a graph representation) and their relationships to each other (e.g., as edges in the graph representation). For instance, the workflow model may comprise a graph representation, of at least one use case, that includes a plurality of nodes, which each represents a user action, event, or response or behavior of the software entity, relevant to the use case, and a plurality of edges, connecting the plurality of nodes to each other, which each represents a relationship between two of the plurality of nodes. The relationship between two nodes may be a trigger, a data flow, or the like.

AI agent 150 may synthesize the workflow model via an AI model 152. For instance, AI agent 150 may generate a prompt that requests a workflow model to be generated from the extracted attributes in a specific format, and input the prompt to a generative language model (e.g., large language model) of AI model(s) 152, to produce the workflow model.

Subprocess 440 may generate at least one future state simulation based on the workflow model that was synthesized in subprocess 430. A future state simulation may comprise any visual or audiovisual representation of the use case(s) represented in the workflow model, including text, graphical elements, audio, virtual reality, augmented reality, and/or the like. For example, the future state simulation may represent a simulated graphical user interface of the software entity to be used for the use case, one or more simulated interactions with the software entity, and/or the like, after the next sprint, after each of two or more future sprints, after completion of the software entity, or the like. It should be understood that the future state simulation for a given sprint may represent a simulated (e.g., predicted) state of the software entity at the end of the sprint. The future state simulation may represent an incremental portion of the overall software entity that is to be built during just the respective sprint.

AI agent 150 may generate each future state simulation via an AI model 152. In particular, AI agent 150 may apply at least one generative AI model to input data, comprising a representation of the workflow model and/or one or more (e.g., at least a subset) of the attribute(s) extracted in subprocess 420, to generate the future state simulation. For instance, AI agent 150 may generate a prompt that requests a specific type of future state simulation be generated from at least one aspect of the workflow model (e.g., for an entire use case or portion of a use case represented in the workflow model) and/or one or more of the attributes extracted in subprocess 420, and input the prompt to a text-to-media generative AI model (e.g., generative language model that responses in natural language to a natural-language input, generative image model that converts text to an image, generative video model that converts text to a video, generative coding model that converts text to software code, etc.), to produce the future state simulation. It should be understood that the future state simulation may be generated in real time or on demand.

As an example, the future state simulation may comprise or consist of a video, for example, generated by a generative video model from AI model(s) 152. The video may depict a use case (e.g., a sequence of one or more user interactions between a user persona and the software entity), a behavior of the software entity, and/or the like. The video may comprise textual and/or audio narration, animations, transitions, visual representations of graphical user interfaces and/or other software components of the software entity, and/or the like.

As another example, the future state simulation may comprise or consist of an interactive demonstration, for example, generated by a generative coding model from AI model(s) 152. The interactive demonstration may comprise a simulated version of the software entity and/or one or more software components of the software entity. The interactive demonstration may be executed within a simulated environment using a game engine or web-based technology (e.g., available as a tool 154). The interactive demonstration may allow what-if analysis, in which users can explore different design scenarios, visual styles, and/or the like.

As another example, the future state simulation may comprise or consist of a narrative script, for example, generated by a generative language model (e.g., large language model) from AI model(s) 152. The narrative script may include a detailed narration of a use case, comprising a sequence of one or more interactions between a user persona and the software entity. For example, the narrative script may describe each user interaction with the software entity, within the use case, including user actions, events, and/or responses or other resulting behavior by the software entity.

As another example, the future state simulation may comprise or consist of a data-driven simulation of the software entity. The data-driven simulation may incorporate real data (e.g., retrieved using a tool 154) and/or synthetic data (e.g., generated by a generative AI model of AI model(s) 152). For example, the data-driven simulation may utilize the real and/or synthetic data to demonstrate the impact of cardinality and/or other metrics on the user experience of the software entity.

As another example, the future state simulation may comprise or consist of one or more exemplary software components of the software entity. For example, each component may be a function that is generated by a generative coding model of AI model(s) 152, to implement at least an aspect of the software entity. In the event that the component is a component of a user interface (e.g., graphical user interface) for the software entity, the component may be provided in alternative styles (e.g., alternative visual styles).

As another example, the future state simulation may comprise or consist of a storyboard. The storyboard may comprise a sequence of one or more drawings (e.g., of a graphical user interface or elements of a graphical user interface) that depict a use case represented by the workflow model that was synthesized in subprocess 430. Each drawing may be generated by a generative image model of AI model(s) 152. The storyboard may also comprise a narrative description of each drawing in the sequence of drawings. The narrative description for each drawing may be generated by a generative language model (e.g., large language model or small language model) of AI model(s) 152.

Subprocess 450 may display the future state simulation that was generated in subprocess 440 via user interface 155. In particular, AI agent 150 may provide a representation of the future state simulation or otherwise provide access to the future state simulation to the user within a graphical user interface of user interface 155 and/or through an audio interface of user interface 155. In addition, AI agent 150 could also provide a representation of the workflow model or otherwise provide access to the workflow model via user interface 155 (e.g., within a graphical user interface and/or through an audio interface).

As an example, assume that the user request that triggers process 400A is to “Generate a network diagram for the new user authentication system.” AI agent 150 may begin by identifying key terms, such as “network diagram,” “user authentication,” and “system.” AI agent 150 may then retrieve user stories and system requirements, related to user authentication, from a requirements repository (e.g., of a project management tool, such as Jira), and access a persona gallery to gather information on patterns of user interaction and potential security considerations. AI agent 150 may also examine existing network diagrams (e.g., represented in Unified Modeling Language (UML)) to identify relevant infrastructure components and patterns. In addition, AI agent 150 may retrieve information from a team directory (e.g., using Lightweight Directory Access Protocol (LDAP), Active Directory (AD), etc.) to identify network engineers responsible for the existing network. To generate the requested network diagram, AI agent 150 may utilize a graph visualization library (e.g., potentially leveraging libraries, such as Graphviz or D3.js) that can interpret structured data and render that structured data as a visual diagram. AI agent 150 translates the gathered data, as the extracted attributes, into a graph representation, comprising nodes and edges, and applies layout algorithms to arrange the diagram logically. This produces a network diagram that may display network components, such as servers, routers, and firewalls, along with the data flow between the displayed network components, security protocols, and authentication mechanisms. The network diagram may utilize standard UML notation or other diagramming tools, and be outputted in any suitable format (e.g., Portable Network Graphics (PNG), Scalable Vector Graphics (SVG), UML, etc.).

As another example, assume that the user request that triggers process 400A is to “Create a storyboard for the user onboarding flow.” AI agent 150 may begin by identifying key terms, such as “storyboard,” “user onboarding,” and “flow.” AI agent 150 may then retrieve user stories and flow diagrams, related to user onboarding, from a requirements repository, and access a persona gallery to gather information on the user's perspective and potential pain points during onboarding. AI agent 150 may also retrieve existing UI components and design patterns from a UX/UI repository. To generate the storyboard, AI agent 150 may use a combination of image generation (e.g., AI model(s) 152) and layout tools (e.g., tool(s) 154). AI agent 150 may utilize a vector graphics library (e.g., SVG.js) to create basic visual frames and incorporate images of UI components retrieved from the UX/UI repository. AI agent 150 may add text overlays and annotations using one or more text-rendering libraries. AI agent 150 may arrange these elements into a sequence of visual panels, representing the user's interaction with the software entity during onboarding. Each visual panel may include a visual representation of a respective UI component, a short description of the user's action(s) and the software entity's response(s), and/or annotations that highlight key UI elements and interactions. The output is a storyboard document or presentation in a suitable format, such as Portable Document Format (PDF), a slide deck, or the like.

As another example, assume that the user request that triggers process 400A is to “Generate a demo script for the new feature that allows users to share files.” AI agent 150 may begin by identifying key terms, such as “demo script,” “share files,” and “feature.” AI agent 150 may then retrieve user stories and feature specifications, related to file sharing, from a requirements repository. and access a persona gallery to gather information on how users might use the file-sharing feature. AI agent 150 may also retrieve UI workflows from a UX/UI repository. To generate the demo script, AI agent 150 may structure the retrieved information into a logical narrative. For example, AI agent 150 may use natural language generation (NLG) techniques (e.g., AI model(S) 152) to produce coherent sentences and paragraphs that incorporate details about use actions, responses from the software entity, and key features. The demo script may be formatted using markdown or a similar text-based markup language, which allows for the clear presentation of instructions and annotations. The demo script may include a narrative describing the user's actions and the software entity's responses, instructions for the presenter (e.g., what to say and what to show on the display), and/or annotations that highlight key features and benefits. The output may be a demo script, in a text or markdown format.

As another example, assume that the user request that triggers process 400A is to “Create a short demo video of the search functionality.” AI agent 150 may begin by identifying key terms, such as “demo video” and “search functionality.” AI agent 150 may then retrieve user stories and feature specifications, related to search, from a requirements repository, as well as UI workflows from a UX/UI repository. AI agent 150 may use a previously generated demo script (e.g., from the immediately preceding example) to generate the demo video. In particular, to generate the demo video, AI agent 150 may utilize screen recording application programming interfaces to capture UI interactions. AI agent 150 may synchronize these screen recordings with audio, generated using a text-to-speech engine, from the narrative in the demo script. AI agent 150 may add text overlays and animations using one or more video-editing libraries (e.g., FFmpeg), which allow AI agent 150 to compose video elements, add transitions, and apply visual effects. The demo video may include screen recordings of the UI interactions, voiceover narration based on the demo script, and/or text overlays and/or animations that highlight key features. The output may be a demo video file in any suitable format (e.g., Moving Picture Experts Group (MPEG)-4).

Subprocess 460 may receive feedback on the output of AI agent 150, including the workflow model, synthesized in subprocess 430, and/or the future state simulation(s), generated in subprocess 440. The user may provide feedback via one or more inputs provided by user interface 155 (e.g., a like input or dislike input within a chat frame of the real-time chat session), via a natural-language input (e.g., by typing feedback or providing a response representing a sentiment into the chat frame of the real-time chat session, speaking the feedback of response to AI agent 150 during the real-time chat session, etc.), and/or the like. The feedback may represent positive and/or negative feedback from a member of the development team, a stakeholder in the software entity, and/or the like.

Subprocess 470 may refine the output of AI agent 150 based on the feedback received in subprocess 460. In particular, AI agent 150 may refine workflow model, synthesized in subprocess 430, and/or the future state simulation(s), generated in subprocess 440, based on the feedback. The refinement may comprise revising a prompt or generating a new prompt for the AI model 152 that generated the workflow model and/or future state simulation, selecting a new AI model 152 to generate the workflow model and/or future state simulation, retraining or fine-tuning an AI model 152 (e.g., via machine learning) to improve the accuracy of its output, retrieving additional or new data through one or more tools 154, utilizing additional or new operation(s) from one or more tools 154, re-executing one or more of subprocesses 410-460, and/or the like.

In an embodiment, the feedback may be received during playback of a future state simulation. For example, a user may provide the feedback, via a typed or spoken natural-language expression, through user interface 155, in real time, as the future state simulation is being displayed (i.e., during subprocess 450). In this case, AI agent 150 may dynamically refine the output, in response to the feedback, in real time, so as to alter the future state simulation during playback.

AI agent 150 may also answer questions about the workflow model, future state simulation(s), and/or underlying data. For example, the user may utilize natural language, input via user interface 155 (e.g., within the chat frame or audio interface of the real-time chat session), to ask AI agent 150 about any of its output, including any of the underlying data used to produce the output. AI agent 150 may utilize one or more AI model(s) 152 (e.g., a generative language model, such as a large language model) and/or one or more tool(s) 154 to answer the user's question(s) via user interface 155.

AI agent 150 may also generate test cases based on the future state simulation that is generated in subprocess 440. For example, a user may request AI agent 150, via user interface 155, to generate a specific test case or set of test cases, a comprehensive set of test cases, and/or the like, for a use case, represented in the workflow model, synthesized in subprocess 430. Responsively, AI agent 150 may utilize one or more models 152 and/or tools 154 to generate data, representing the requested test case(s), which can then be run against the current or future software entity (e.g., after the current sprint). In this manner, the user can ensure that the implemented software entity matches the intended design.

FIG. 4B illustrates a process 400B for generating a development timeline, according to an embodiment. Process 400B may be implemented by AI agent 150. In particular, AI agent 150 is configured to analyze design artifacts and generate a project development timeline from these design artifacts. It should be understood that AI agent 150 may utilize one or more models 152 and/or one or more tools 154 to perform this analysis and generation, for example, in one or more iterations of model process M and/or tool process T. For instance, tool(s) 154 may be used to retrieve and/or analyze data, and model(s) 152 may be used to analyze that data and/or generate project development timelines from that data.

Process 400B may be performed by AI agent 150 within a real-time chat session between at least one user and AI agent 150, and potentially the same real-time chat session as process 400A. The real-time chat session may occur within a chat frame of a graphical user interface of user interface 155, through an audio interface, through an audiovisual interface, and/or the like. Process 400B may be initiated in response to receiving a user request from at least one user for a project development timeline. The user request may comprise or consist of a natural-language expression.

In an embodiment, the project development timeline comprises a sequence of one or more, and generally a plurality of, sprints. Each sprint may be defined by a time period for the sprint (e.g., a time duration specified as a number of hours, days, weeks, months, etc., start and/or end dates, and/or the like), an objective of the sprint (e.g., an increment of the software product to be built within the time period, which may be defined by a set of product components, use cases, bug fixes, portion of the product backlog, etc.), a set of team members assigned to the sprint, an assignment of tasks to each team member assigned to the sprint, a definition of done (DoD) for tasks in the sprint (e.g., one or more criteria that establishes when a task is complete), a schedule or frequency of team meetings during the sprint, and/or the like. In some cases, each sprint may be a fixed time period (e.g., one to four weeks), with the objective for each sprint selected to be feasible for the fixed time period.

Subprocesses 410 and 420 in process 400B may be similar or identical to subprocesses 410 and 420, respectively, in process 400A. Thus, any description of these subprocesses with respect to process 400A applies equally to these subprocesses with respect to process 400B, and vice versa. It should be understood that the specific subset of design data, received in subprocess 410, and the specific subset of attributes that are extracted in subprocess 420, may differ between processes 400A and 400B, but that the framework may otherwise be the same. In process 400B, the design data and attributes may be relevant to a project development timeline. In particular, project management data, within the design data, may be a fertile source of attributes for generation of the project development timeline.

In process 400B, compared to process 400A, subprocesses 430 and 440 are replaced with subprocess 435. Subprocess 435 may generate a project development timeline, including, for example, a sequence of one or more sprints, for the software entity to be built, based on the attributes that were extracted in subprocess 420. It should be understood that subprocess 435 could comprise a subprocess identical or similar to subprocess 430, to synthesize a workflow model that may be used to generate the project development timeline. For instance, the workflow model may be used by an AI model 152 (e.g., generative language model) to determine the increments of the software entity to be built in each sprint. Alternatively, an AI model 152 (e.g., generative language model) may be applied directly to the attributes to determine the project development timeline. In either case, AI agent 150 may generate a prompt that requests a project development timeline be generated from the workflow model and/or one or more of the attributes extracted in subprocess 420, and input the prompt to a generative AI model (e.g., generative language model, such as a small or large language model), to produce the project development timeline. The prompt may define the software entity (e.g., as a workflow model), including any desired and/or mandatory attributes, a total acceptable time period for the project, requirements for each sprint, the output format for the project development timeline (e.g., how each sprint should be defined), and/or the like. It should be understood that the project development timeline may be generated in real time or on demand.

Subprocesses 450 in process 400B may be similar or identical to subprocess 450 in process 400A, except that the project development timeline is being displayed (e.g., within the graphical user interface of user interface 155), instead of a future state simulation. The project development timeline may be displayed as text (e.g., a natural-language expression), a diagram (e.g., project timeline, event timeline, Gantt chart, roadmap, vertical timeline, graphical timeline, interactive timeline, etc.), and/or in any other suitable format.

Subprocesses 460 and 470 in process 400B may be similar or identical to subprocesses 460 and 470, respectively, in process 400A. Thus, any description of these subprocesses with respect to process 400A applies equally to these subprocesses with respect to process 400B, and vice versa. However, it should be understood that the feedback, received in subprocess 460 and used to refine the output of AI agent 150 in subprocess 470, will be feedback regarding the project development timeline, rather than a workflow model or future state simulation.

### 5. Example Collaboration With AI Agent

As discussed elsewhere herein, AI agent 150 may act as a member of a development team, during one or more meetings at any stage in the development process for a software entity. To facilitate participation by AI agent 150, AI agent 150 may comprise a listening component that receives the output of a speech-to-text engine that is continuously processing audio inputs, captured by at least one microphone during the meeting. AI agent 150 may also provide outputs to a user interface 155 that comprises both a display within the meeting, to display visual elements, and a text-to-speech engine that converts generated natural-language text into audio, to be output via a speaker system within the meeting. In this manner, AI agent 150 is seamlessly integrated into the meeting, as another participant that contributes knowledge from a wide knowledge base and can generate future state simulations on demand. The meeting may be an in-person meeting, within a physical meeting room, between members of the development team, in which case AI agent 150 may execute on or be communicatively coupled to a hardware system, within the meeting room, that comprises a microphone, display, and speaker. Alternatively, the meeting may be a virtual meeting, within an audiovisual tele-conferencing application, in which case AI agent 150 may execute on a remote platform that has access to the virtual meeting.

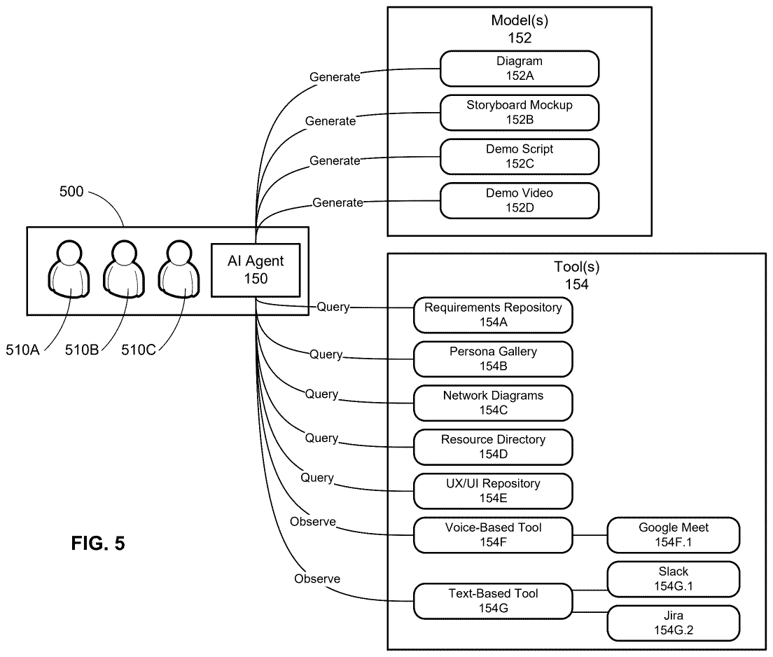

FIG. 5 illustrates an example data flow in an example design collaboration with AI agent 150, according to an embodiment. In this example, a 4IAB collaboration model is assumed, with a development team 500 comprising a user-experience designer 510A, named Sarah, who focuses on user experience and usability of the software entity to be built, a product manager 510B, named David, who defines the product requirements and business goals of the software entity to be built, a software engineer or architect 510C, named Alex, who is responsible for designing the service architecture and technical implementation of the software entity to be built, and an AI agent 150, denoted “AI.” AI agent 150 may be configured to automatically listen to the conversation between David, Sarah, and Alex and respond to requests or other prompts. It should be understood that AI agent 150 may be configured to receive audio data from the conversation, and provide responses in visual and/or audio format. AI agent 150 may utilize model(s) 152 to produce diagrams 152A, storyboard mockups 152B, demo scripts 152C, demo videos 152D, and/or the like. AI agent 150 may also have access, via one or more tools 154, to a requirements repository 154A, persona gallery 154B, network diagrams 154C, resource directory 154D, UX/UI repository 154E, voice-based tool 154F (e.g., which provides access to a virtual meeting tool, such as Google Meet 154F.1), text-based tool 154G (e.g., which provides access to tools, such as Slack 154G.1 and/or Jira 154G.2), and/or the like.

The meeting may unfold as follows:
David: [initiates an audiovisual tele-conference via a virtual meeting tool, such as Google Meet 154F.1, and initiates execution of AI agent 150, which observes the tele-conference, in real time, via voice-based tool 154F]
David: Alright team, let's kick off Project Phoenix. Our main goal is to build a seamless integration for our Point-of-Sale system with our online inventory and customer loyalty programs. Sarah, what are your initial thoughts on the user experience?
Sarah: I'm thinking we need to focus on a quick and reliable transaction process at the POS. We need to ensure that inventory updates are real-time and customer loyalty points are accurately applied. I've sketched a few initial user interaction flows at the register.
AI: [queries UX/UI repository 154E]
Alex: From an architectural standpoint, we need to consider data consistency and security across the POS, online inventory, and loyalty platforms. We need to define the data exchange protocols and ensure robust error handling. Also, do we know how many runtimes an average customer has? Are we talking about an order of magnitude increase?
AI: [queries network diagrams 154C and resource directory 154D]
AI: Our average customer has between five and ten runtimes, with some customers having a maximum of 793 in a single account. Talking about a point-of-sale use case might represent anywhere between a two and three order of magnitude change.
AI: [queries requirements repository 154A]
David: That's a significant increase. Alex, that's definitely something we need to account for in our architecture. Great. AI, can you take these initial flows and generate a preliminary simulation? We need to see how these ideas translate into a real-world POS transaction.
AI: [queries requirements repository 154A, generates demo video 152D of a POS transaction flow, including inventory updates and loyalty point application, based on provided user flows and system architecture considerations, and displays demo video 152D]
AI: Displaying video simulation now.
Sarah: Hmm, I see a potential issue during the loyalty point application. The delay seems a bit long. Can we try optimizing the communication with the loyalty server?
Alex: I observe that the simulation highlights the data synchronization between the POS and the inventory system. This is useful. Can we also simulate the potential impact of network latency on the transaction speed?
David: Yes, AI, can you generate a what-if scenario simulating a 2-second network latency during peak hours?
AI: [generates demo video 152D of simulated what-if scenario with increased network latency, and displays demo video 152D]
AI: Displaying simulation with increased network latency.
Alex: As suspected, the transaction time increases significantly. We need to implement a local caching mechanism for inventory data.
Sarah: I also notice that the error messages during a failed loyalty point application are too technical for the cashier. Can we make them more user-friendly and provide specific guidance on how to resolve the issue?
David: Excellent feedback. AI, can you generate an update to the simulation with the proposed changes—optimized loyalty server communication, local inventory caching, and user-friendly error messages?
AI: [generates updated demo video 152D with requested changes, and displays demo video 152D]
AI: Displaying updated simulation now.
David: This is much better. Seeing the transaction flow with these changes gives us a much clearer picture.
Sarah: Yes, this simulation has helped us identify and address potential issues early in the design process, especially the speed and reliability of the POS transaction.
Alex: This also gives me a better idea on how to structure the data synchronization and caching mechanisms, especially with the increased runtimes. This will save us time later in the project.
David: Perfect. Let's document these changes and move on to the next phase. AI, please generate a detailed script of the final simulation for our records.
AI: [generates detailed demo script 152C, and makes demo script 152C available for download]
AI: The script is available for download at [link].
David: This updated simulation aligns perfectly with our goals for POS integration. Now, AI, let's solidify this into concrete documentation. Can you generate the necessary diagrams and a preliminary sprint plan?
AI: Certainly.
AI: [queries requirements repository 154A, generates diagram 152A of use case based on finalized POS transaction flow and requirements, and displays diagram 152A, illustrating interactions between the cashier and POS system]
Sarah: These use case diagrams are great. They clearly illustrate the cashier's interactions during a typical transaction.
AI: [generates diagrams 152A]
Alex: Yes, and I observe the integration points with the online inventory and loyalty systems, which is helpful for architectural planning, especially considering the increased runtimes.
AI: [generates diagrams 152A that detail the sequence of interactions between system components during a POS transaction, and displays diagrams 152A, illustrating the flow of messages between the POS, inventory, and loyalty systems]
Alex: Excellent. The sequence diagrams clearly depict the data exchange and synchronization processes, and it is helpful when thinking about the runtimes.
AI: [generates diagrams 152A]
David: This is precisely what we need. AI, can you now generate an architecture diagram based on the use cases and sequence diagrams?
AI: [generates diagram 152A of architecture based on the use cases and sequence diagrams, and displays diagram 152A, illustrating the POS, inventory, and loyalty systems, and their connections]
Alex: Perfect. The architecture diagram provides a clear overview of the integration architecture, and it helps to visualize the impact of the runtimes. This will be invaluable for our development team.
AI: [generates diagrams 152A]
David: Fantastic. Now, let's move on to planning our sprints. AI, please generate a preliminary sprint plan based on the finalized requirements and the generated diagrams. We'll need to prioritize tasks and estimate effort.
AI: [observes Jira 154G.2 via text-based tool 154G, generates preliminary sprint plan, queries use cases, sequence diagrams, architecture diagram, and project requirements to estimate effort and prioritize tasks, and displays the sprint plan, outlining tasks, estimated effort, and sprint assignments]
David: This is a solid starting point. The task breakdown and effort estimates are reasonable. We can refine this further during our sprint planning meeting.
AI: [observes Jira 154G.2]
Sarah: I appreciate that the sprint plan includes tasks related to POS usability testing and performance optimization, especially considering the higher runtimes.
AI: [observes Jira 154G.2]
Alex: The plan also considers the integration dependencies, which will help us avoid bottlenecks with the increase in runtimes.
AI: [observes Jira 154G.2]
David: Excellent work, team. AI, please generate and save all the generated diagrams and the sprint plan to our project repository.
AI: [queries requirements repository 154A, and observes Jira 154G.2]
AI: [saves generated diagrams and sprint plan to Jira 154G.2, generates and displays a summary report of the meeting, and observes Slack 154G.1 via text-based tool 154G]
AI: Diagrams and sprint plan saved to project repository.
David: Thank you, AI. This has been an incredibly productive kickoff meeting. We've effectively translated our initial ideas into concrete plans and documentation for the POS integration, and we have a much better idea about the runtimes.
AI: [observes Slack 154G.1 via text-based tool 154G]
Sarah: I agree. The simulations and diagrams have helped us visualize and refine our POS transaction flow.
AI: [queries UX/UI repository 154E]
Alex: The automated generation of the sprint plan will save us significant time in planning the integration, especially when dealing with the runtimes.
AI: [queries network diagrams 154C]
David: Let's schedule our sprint planning meeting for tomorrow morning to finalize the details.
AI: [observes Slack 154G.1 via text-based tool 154G]
David: [ends audiovisual tele-conference, which terminates execution of AI agent 150]

The above description of the disclosed embodiments is provided to enable any person skilled in the art to make or use the invention. Various modifications to these embodiments will be readily apparent to those skilled in the art, and the general principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly not limited.

As used herein, the terms “comprising,” “comprise,” and “comprises” are open-ended. For instance, “A comprises B” means that A may include either: (i) only B; or (ii) B in combination with one or a plurality, and potentially any number, of other components. In contrast, the terms “consisting of,” “consist of,” and “consists of” are closed-ended. For instance, “A consists of B” means that A only includes B with no other component in the same context.

Combinations, described herein, such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, and any such combination may contain one or more members of its constituents A, B, and/or C. For example, a combination of A and B may comprise one A and multiple B's, multiple A's and one B, or multiple A's and multiple B's.

What is claimed is:

1. A method comprising using at least one hardware processor to, by an artificial intelligence (AI) agent, within a real-time chat session between at least one user and the AI agent:
receive a user request from the at least one user for a future state simulation that simulates a future state of a software entity;
retrieve design data for the software entity;
extract a plurality of attributes from the design data;
synthesize a workflow model of the software entity based on the plurality of attributes;
apply at least one generative AI model to input data, comprising a representation of the workflow model, to generate the future state simulation; and
display the future state simulation within a graphical user interface.

2. The method of claim 1, wherein the user request comprises a natural-language expression.

3. The method of claim 1, wherein the software entity has not yet been built.

4. The method of claim 1, wherein the design data comprise one or more of a specification of each of one or more use cases, a profile of each of one or more personas, one or more diagrams of an architecture of the software entity, one or more user stories, project management data, a database of requirements for the software entity, one or more software components that are available for incorporation into the software entity, or a user-interface framework to be used by the software entity.

5. The method of claim 1, wherein the plurality of attributes comprises one or more of roles of personas, identification of one or more software components, one or more data flows, one or more user actions, one or more use cases, or cardinalities for relationships between software components.

6. The method of claim 1, wherein the at least one generative AI model comprises a generative video model, wherein the future state simulation comprises a video, generated by the generative video model, depicting a use case represented by the workflow model, and wherein the use case comprises a sequence of one or more interactions between a user persona and the software entity.

7. The method of claim 1, wherein the at least one generative AI model comprises an interactive demonstration of the software entity, wherein the interactive demonstration comprises a simulated version of the software entity with which users can interact, and wherein displaying the future state simulation comprises executing the interactive demonstration within a simulated environment.

8. The method of claim 1, wherein the at least one generative AI model comprises a large language model, wherein the future state simulation comprises a narrative script, generated by the large language model, of a use case represented by the workflow model, and wherein the use case comprises a sequence of one or more interactions between a user persona and the software entity.

9. The method of claim 1, wherein the future state simulation comprises a data-driven simulation of the software entity that incorporates one or both of real or synthetic data to demonstrate an impact of one or more metrics on a user experience of the software entity.

10. The method of claim 1, wherein the at least one generative AI model comprises a generative coding model, and wherein the future state simulation comprises one or more software components of the software entity.

11. The method of claim 1, wherein the at least one generative AI model comprises a generative image model, wherein the future state simulation comprises a storyboard that includes one or more drawings, generated by the generative image model, and wherein the one or more drawings depict a use case represented by the workflow model.

12. The method of claim 11, wherein the at least one generative AI model further comprises a generative language model, wherein the storyboard includes a narrative description, generated by the generative language model, of each of the one or more drawings.

13. The method of claim 1, wherein the workflow model comprises a graph representation of at least one use case, wherein the graph representation comprises a plurality of nodes and a plurality of edges connecting the plurality of nodes to each other, wherein each of the plurality of nodes represents a user action, event, or response or behavior of the software entity, and wherein each of the plurality of edges represents a relationship between two of the plurality of nodes.

14. The method of claim 1, further comprising using the at least one hardware processor to, by the AI agent, within the real-time chat session:
receive a user request from the at least one user for a project development timeline;
retrieve second design data for the software entity;
extract a second plurality of attributes from the second design data;
apply at least one second generative AI model to second input data, comprising the second plurality of attributes, to generate the project development timeline; and
display the project development timeline within the graphical user interface.

15. The method of claim 14, wherein the at least one second generative AI model comprises a large language model, and wherein applying the at least one second generative AI model comprises:
generating a prompt based on the second input data; and
inputting the prompt to the at least one second generative AI model to produce the project development timeline.

16. The method of claim 1, wherein applying the at least one generative AI model comprises:
generating a prompt based on the input data; and
inputting the prompt to the at least one generative AI model to produce the future state simulation.

17. The method of claim 1, wherein the input data further comprise at least a subset of the plurality of attributes.

18. The method of claim 1, wherein the real-time chat session is an audiovisual tele-conference, and wherein the AI agent is a participant, along with the at least one user, in the audiovisual tele-conference.

19. A system comprising:
at least one hardware processor; and
an artificial intelligence (AI) agent comprising software that is configured to, when executed by the at least one hardware processor, within a real-time chat session between at least one user and the AI agent,
receive a user request from the at least one user for a future state simulation that simulates a future state of a software entity,
retrieve design data for the software entity,
extract a plurality of attributes from the design data,
synthesize a workflow model of the software entity based on the plurality of attributes,
apply at least one generative AI model to input data, comprising a representation of the workflow model, to generate the future state simulation, and
display the future state simulation within a graphical user interface.

20. A non-transitory computer-readable medium having instructions stored therein, wherein the instructions, when executed by a processor, cause the processor to, within a real-time chat session between at least one user and the AI agent:
receive a user request from the at least one user for a future state simulation that simulates a future state of a software entity;
retrieve design data for the software entity;
extract a plurality of attributes from the design data;
synthesize a workflow model of the software entity based on the plurality of attributes;
apply at least one generative AI model to input data, comprising a representation of the workflow model, to generate the future state simulation; and
display the future state simulation within a graphical user interface.
